(19) United States
(12) Patent Application Publication
(10) Pub. No.: US 2024/0258148 A1
(43) Pub. Date: Aug. 1, 2024

(54) Centering Device, Centering Method and Substrate Processing Apparatus

(71) Applicant: SCREEN Holdings Co., Ltd., Kyoto-shi (JP)

(72) Inventors: Itsuki KAJINO, Kyoto (JP); Shuhei NEMOTO, Kyoto (JP)

(21) Appl. No.: 18/419,384

(22) Filed: Jan. 22, 2024

(30) Foreign Application Priority Data
Jan. 30, 2023 (JP) 2023-011958

(51) Int. Cl. H01L 21/68; H01L 21/67

(52) U.S. Cl. CPC H01L 21/68; H01L 21/6708

(57) ABSTRACT

This invention relates to a centering device, a centering method and a substrate processing apparatus. substrate supported on a substrate support is surrounded by a first contact member located at a first reference position, a second contact member located at a second reference position and a third contact member located at a third reference position in the horizontal plane. These three contact members gradually approach the substrate while keeping distances from a center of the substrate support equal by repeating the minute movements. Considering that the minute movement directions of the second and third contact members are different from each other, first and second angles are each set in a range of 40° or larger and 60° or smaller.

### CROSS REFERENCE TO RELATED APPLICATION

The disclosure of Japanese Patent Application No. 2023-011958 filed on Jan. 30, 2023 including specification, drawings and claims is incorporated herein by reference in its entirety.

### BACKGROUND OF THE INVENTION

### 1. Field of the Invention

This invention relates to a centering technique for aligning a center of a disk-shaped substrate placed on the upper surface of a substrate support with a center of the substrate support and a substrate processing apparatus for processing a substrate utilizing the centering technique. This process includes a bevel etching process.

### 2. Description of the Related Art

In a known substrate processing apparatus, a chemical liquid process or a cleaning process is performed by supplying a processing liquid to a peripheral edge part of a substrate such as a semiconductor wafer while rotating the substrate. In an apparatus described in Japanese Patent Application Laid-Open No. 2019-149423, for example, a substrate is held under suction while being supported from below by a spin chuck (corresponding to an example of a “substrate support” of the present invention). In response to this, before processing the substrate, a so-called centering process is performed to reduce the eccentricity of the substrate relative to the spin chuck.

### SUMMARY OF INVENTION

In the above conventional apparatus, the centering operation is performed in two steps. First, the amount of eccentricity of the substrate from the spin chuck is measured. Subsequently, the center of the substrate is moved toward the center of the spin chuck (axis of rotation) by horizontally pushing the substrate on the spin chuck by a pusher. Therefore, there remains room for improvement in throughput.

This invention was developed in view of the above problem and aims to provide a centering technique capable of aligning a center of a disk-shaped substrate placed on the upper surface of a substrate support with a center of the substrate support with excellent throughput and a substrate processing apparatus using this centering technique.

A first aspect of the invention is a centering device for positioning a substrate on a substrate support such that a center of the disk-shaped substrate placed in a horizontal posture on an upper surface of the substrate support is aligned with a center of the substrate support. The device includes: a first contact member movable in a horizontal plane in a first horizontal direction from a first reference position that is separated from the center of the substrate support by a reference distance longer than a radius of the substrate toward the center of the substrate support, the first horizontal direction being a direction toward the center of the substrate support; a second contact member movable in the horizontal plane in a second horizontal direction from a second reference position that is inclined by a first angle with respect to a virtual line extending in the first horizontal direction from the center of the substrate support and separated from the center of the substrate support by the reference distance on a side opposite to the first contact member with respect to the center of the substrate support, the second horizontal direction being different from a direction toward the center of the substrate support and extending toward the substrate; a third contact member movable in the horizontal plane in a third horizontal direction from a third reference position that is inclined by a second angle with respect to a virtual line and separated from the center of the substrate support by the reference distance on a side opposite to the first contact member with respect to the center of the substrate support and opposite to the second contact member with respect to the virtual line, the third horizontal direction being different from a direction toward the center of the substrate support and extending toward the substrate; a moving mechanism configured to move the first contact member, the second contact member and the third contact member respectively in the first horizontal direction, the second horizontal direction and the third horizontal direction; and a controller configured to perform an aligning the substrate with respect to the substrate support by controlling the moving mechanism, wherein the first angle is in a range of 40 or larger and 60 or smaller, the second angle is in a range of 40 or larger and 60 or smaller, and the controller is configured to control the moving mechanism to repeat minute movements of moving the first contact member, the second contact member and the third contact member respectively by a first movement amount, a second movement amount and a third movement amount until contact of all of the first contact member, the second contact member and the third contact member with the substrate is completed so that distances of the first contact member, the second contact member and the third contact member from the center of the substrate support are kept equal.

A second aspect of the invention is a centering method for positioning a substrate on a substrate support such that a center of the disk-shaped substrate placed in a horizontal posture on an upper surface of the substrate support is aligned with a center of the substrate support. The method includes: placing the substrate on the upper surface of the substrate support with a first contact member located at a first reference position separated from the center of the substrate support by a reference distance longer than a radius of the substrate, a second contact member located at a second reference position inclined by a first angle with respect to a virtual line extending through the center of the substrate support from the first reference position and separated from the center of the substrate support by the reference distance on a side opposite to the first contact member with respect to the center of the substrate support and a third contact member located at a third reference position inclined by a second angle and separated from the center of the substrate support by the reference distance on a side opposite to the first contact member with respect to the center of the substrate support and opposite to the second contact member with respect to the virtual line; repeating minute movements of moving the first contact member in a first horizontal direction from the first reference position toward the center of the substrate support by a first movement amount, moving the second contact member in a second horizontal direction different from a direction toward the center of the substrate support and extending toward the substrate from the second reference position by a second movement amount and moving the third contact member in a third horizontal direction different from a direction toward the center of the substrate support and extending toward the substrate from the third reference position by a third movement amount so that distances of the first contact member, the second contact member and the third contact member from the center of the substrate support are kept equal with the substrate placed horizontally movably on the upper surface of the substrate support; and stopping the minute movements if sandwiching of the substrate by the first contact member, the second contact member and the third contact member is confirmed while the minute movements are repeated, wherein the first angle is in a range of 40 or larger and 60 or smaller, and the second angle is in a range of 40 or larger and 60 or smaller.

A third aspect of the invention is a substrate processing apparatus. The apparatus includes: a substrate support having an upper surface and being configured to support a substrate in a horizontal posture; the centering device according to claim 1; a suction unit configured to suck and hold the substrate on the substrate support by exhausting air between the substrate positioned by the centering device and the substrate support; a rotation driver configured to rotate the substrate support sucking and holding the substrate about a center of the substrate support; and a processing liquid supply mechanism configured to supply a processing liquid to a peripheral edge part of the substrate rotated about the center of the substrate support integrally with the substrate support.

In the invention thus configured, the substrate is surrounded by the first contact member located at the first reference position, the second contact member located at the second reference position and the third contact member located at the third reference position in the horizontal plane. These three contact members gradually approach the substrate while keeping the distances from the center of the substrate support equal by repeating the minute movements. During these approaching movements, the contact members successively contact the substrate and horizontally move the substrate toward the center of the substrate support. As a result, the center of the substrate sandwiched by these three contact members is aligned with the center of the substrate support.

Moreover, as described in detail later, the second contact member and the third contact member are arranged as described above, taking into consideration that directions of the minute movements of the second contact member and the third contact member are different from the direction toward the center of the substrate support. Thus, excellent centering accuracy is obtained.

As described above, according to the invention, the center of the disk-shaped substrate placed on the upper surface of the substrate support can be accurately aligned with the center of the substrate support only by repeating the minute movements of the three contact members, and a centering operation of the substrate can be accurately performed with excellent throughput.

All of a plurality of constituent elements of each aspect of the invention described above are not essential and some of the plurality of constituent elements can be appropriately changed, deleted, replaced by other new constituent elements or have limited contents partially deleted in order to solve some or all of the aforementioned problems or to achieve some or all of effects described in this specification. Further, some or all of technical features included in one aspect of the invention described above can be combined with some or all of technical features included in another aspect of the invention described above to obtain one independent form of the invention in order to solve some or all of the aforementioned problems or to achieve some or all of the effects described in this specification.

### BRIEF DESCRIPTION OF THE DRAWINGS

FIG. 1 is a plan view showing a schematic configuration of a first embodiment of a substrate processing apparatus according to the invention.

FIG. 2 briefly shows a configuration in a first embodiment of the substrate processing apparatus.

FIG. 3 is a perspective view showing the configurations of a substrate holder and a centering mechanism of the substrate processing apparatus.

FIG. 4 is a diagram schematically showing the configuration of a contact member that can be employed in the centering mechanism and the relationship with the notch of the substrate.

FIG. 5 is a diagram schematically showing the operation of the centering mechanism.

FIG. 6A is a diagram schematically showing the positional relationship between the contact member and the center of the spin base before and after the minute movement.

FIG. 6B is a diagram schematically showing pushing force exerted on the substrate from the contact member.

FIG. 7 is a graph showing variations in load torque with respect to variations in a distance from a center of a base to a contact surface in the first embodiment.

FIG. 8 is a graph showing variations of a Y-directional component of pushing force and a maximum eccentricity as a function of angle.

FIG. 9A is a diagram schematically showing centering characteristics when first and second angles are set at 30° respectively.

FIG. 9B is a diagram schematically showing centering characteristics when the first and second angles are set at 45° respectively.

FIG. 9C is a diagram schematically showing centering characteristics when the first and second angles are set at 60° respectively.

FIG. 10 is a diagram schematically showing the configuration of a contact member adopted in the third embodiment of the centering device according to the invention and a relationship with a notch of a substrate.

FIG. 11 is a diagram schematically showing the configuration of a fourth embodiment of the centering device according to the invention.

### DETAILED DESCRIPTION OF THE PREFERRED EMBODIMENTS

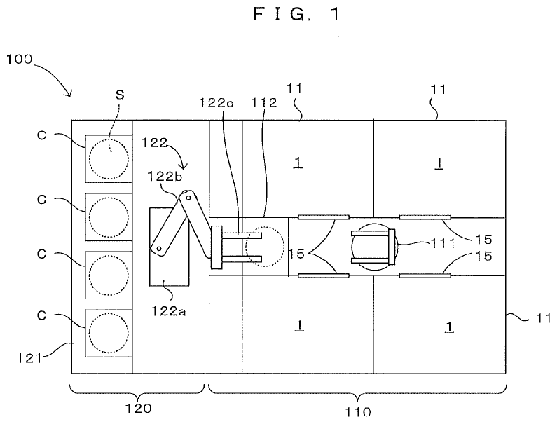

FIG. 1 is a plan view showing a schematic configuration of a first embodiment of a substrate processing apparatus according to the invention. This figure is a diagram not showing the external appearance of the apparatus, but showing an internal structure of a substrate processing system 100 by excluding an outer wall panel and other partial configurations. This substrate processing system 100 is, for example, a single-wafer type apparatus installed in a clean room and configured to process substrates W each having a circuit pattern (hereinafter, referred to as a “pattern”) only on one principal surface one by one. A substrate processing with processing fluid is carried out in a processing unit 1 equipped in the substrate processing system 100. In this specification, a pattern formation surface (one principal surface) formed with the pattern is referred to as a “front surface” and the other principal surface not formed with the pattern on an opposite side is referred to as a “back surface”. Further, a surface facing down is referred to as a “lower surface” and a surface facing up is referred to as an “upper surface”. Further, in this specification, the “pattern formation surface” means a surface of the substrate where an uneven pattern is formed in an arbitrary region regardless of whether the surface is flat, curved or uneven.

Here, various substrates such as semiconductor wafers, glass substrates for photomask, glass substrates for liquid crystal display, glass substrates for plasma display, substrates for FPD (Flat Panel Display), optical disk substrates, magnetic disk substrates and magneto-optical disk substrates can be applied as the “substrate” in this embodiment. Although the substrate processing apparatus used in processing semiconductor wafers is mainly described as an example with reference to the drawings below, application to the processing of various substrates illustrated above is also possible.

As shown in FIG. 1, the substrate processing system 100 includes a substrate processing area 110 for processing the substrate S. An indexer station 120 is provided adjacent to this this substrate processing area 110. The indexer station 120 includes a container holder 121 capable of holding a plurality of containers C for housing the substrates W (FOUPs (Front Opening Unified Pods), SMIF (Standard Mechanical Interface) pods, OCs (Open Cassettes) for housing a plurality of the substrates W in a sealed state), and an indexer robot 122 for taking out an unprocessed substrate S from the container C by accessing the container C held by the container holder 121 and housing a processed substrate S in the container C. A plurality of the substrates W are housed substantially in a horizontal posture in each container C.

The indexer robot 122 includes a base 122a fixed to an apparatus housing, an articulated arm 122b provided rotatably about a vertical axis with respect to the base 122a, and a hand 122c mounted on the tip of the articulated arm 122b. The hand 122c is structured such that the substrate S can be placed and held on the upper surface thereof. Such an indexer robot including the articulated arm and the hand for holding the substrate is not described in detail since being known.

In the substrate processing area 110, a mounting table 112 is provided to place a substrate S from the indexer robot 122. Also, in a plan view, a substrate conveyor robot 111 is positioned almost in the center of the substrate processing area 110. Furthermore, a plurality of processing units 1 are arranged to surround this substrate conveyor robot 111. The substrate conveyor robot 111 randomly accesses these processing units 1 and transfers the substrates W. On the other hand, each processing unit 1 performs a predetermined processing to the substrate S. In this embodiment, these processing units 1 have the same function. Thus, a plurality of the substrates W can be processed in parallel. In the embodiment, one of the processing units 1 corresponds to the substrate processing apparatus 10 according to the invention.

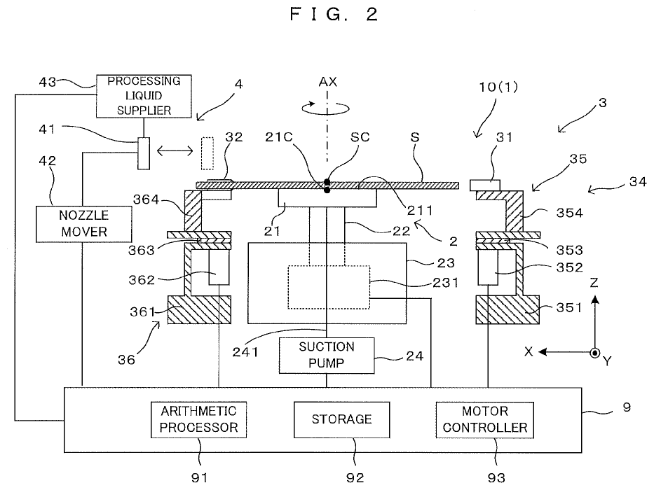

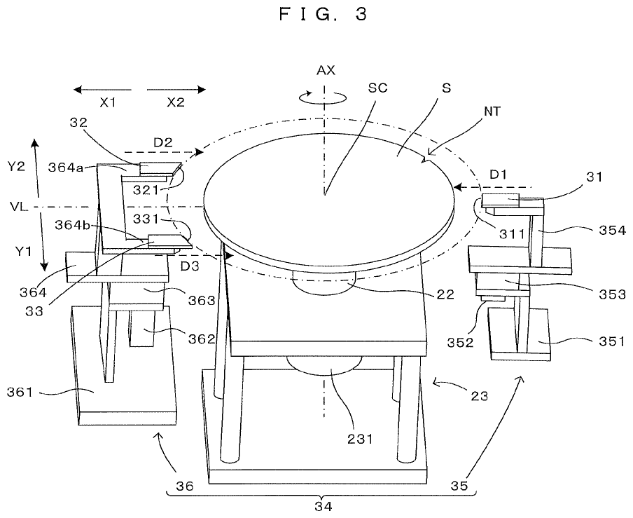

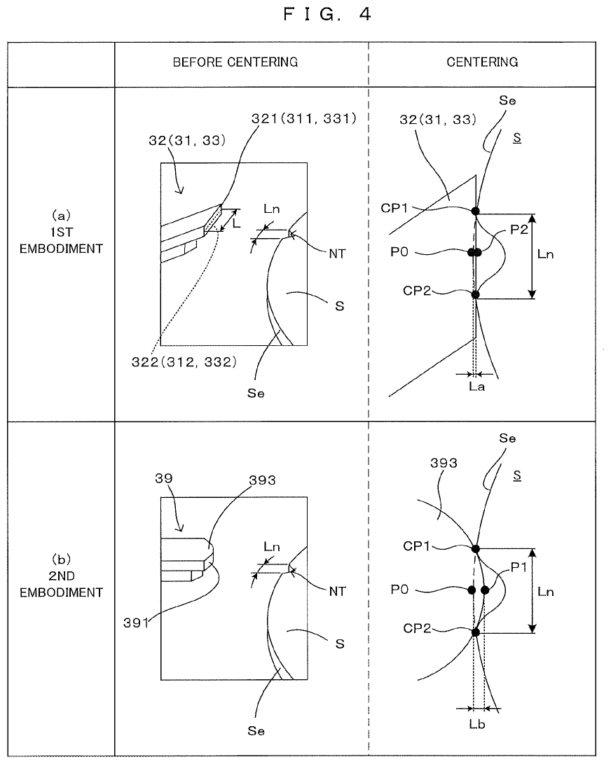

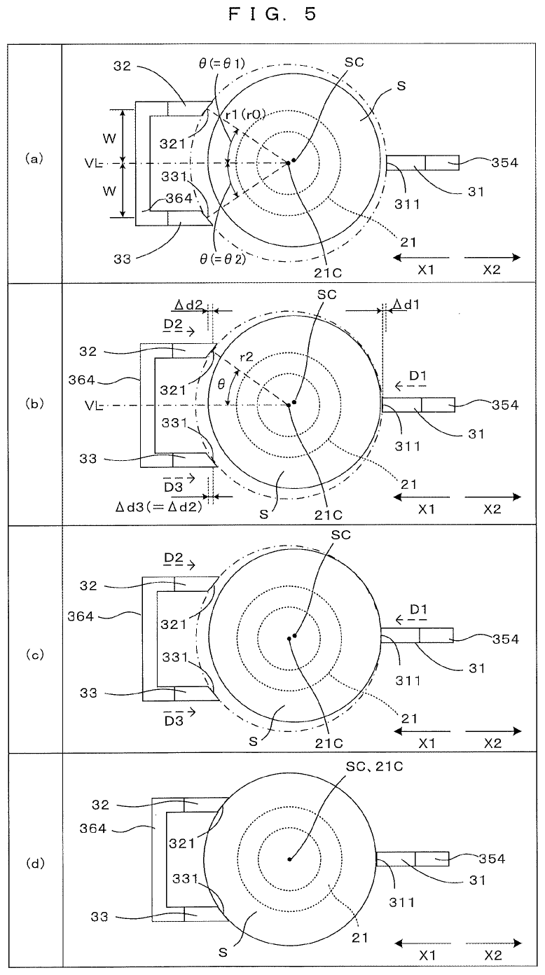

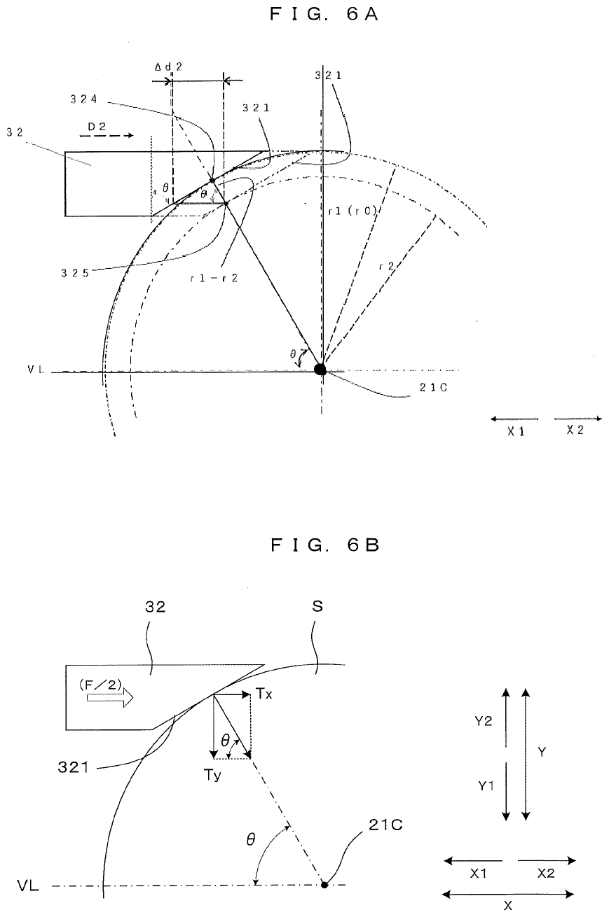

FIG. 2 briefly shows a configuration in a first embodiment of the substrate processing apparatus. FIG. 3 is a perspective view showing the configurations of a substrate holder and a centering mechanism of the substrate processing apparatus. FIG. 4 is a diagram schematically showing the configuration of a contact member that can be employed in the centering mechanism and the relationship with the notch of the substrate. FIG. 5 is a diagram schematically showing the operation of the centering mechanism. FIG. 6A is a diagram schematically showing the positional relationship between the contact member and the center of the spin base before and after the minute movement. FIG. 6B is a diagram schematically showing pushing force exerted on the substrate from the contact member. The substrate processing apparatus 10 is an apparatus that performs a bevel etching process as an example of a “process” of the present invention, and supplies a processing liquid to a peripheral edge part of an upper surface of the substrate S in a processing chamber. For this purpose, the substrate processing apparatus 10 includes a substrate holder 2, a centering mechanism 3 forming a principal structure of a centering device according to the present invention, and a processing liquid supply mechanism 4. Operations of these structures are controlled by a controller 9 responsible for control over the apparatus entirely.

The substrate holder 2 includes a spin base 21 that is a member of a smaller circular plate shape than the substrate S. The spin base 21 is supported on a rotary support shaft 22 extending downward from a central part of a lower surface of the spin base 21 in such a manner as to locate an upper surface 211 of the spin base 21 horizontally. The rotary support shaft 22 is rotatably supported by a rotary driver 23. The rotary driver 23 includes a built-in rotary motor 231. The rotary motor 231 rotates in response to a control command from the controller 9. In response to receipt of resultant rotary driving force, the spin base 21 rotates about a vertical axis AX (alternate long and short dashed lines) extending in a vertical direction while passing through a center 21C of the spin base 21. In FIG. 2, a top-bottom direction corresponds to the vertical direction. A plane perpendicular to the plane of paper of FIG. 2 is a horizontal plane. To clearly show a relationship in terms of direction, a coordinate system defining a Z axis as the vertical direction and an XY plane as the horizontal plane is given in FIG. 2 and its subsequent drawings, if appropriate.

The upper surface 211 of the spin base 21 has a dimension by which the substrate S is supportable to allow the substrate S to be placed on the upper surface 211 of the spin base 21. Although not shown in the drawings, the upper surface 211 is provided with a plurality of suction holes or suction grooves, for example. Such suction holes or grooves are connected to a suction pump 24 through a suction pipe 241. This suction pump 24 serves as an example of the “suction unit” of the invention. In response to a control command from the controller 9, the suction pump 24 operates to apply suction power from the suction pump 24 to the spin base 21. As a result, air is exhausted from between the upper surface 211 of the spin base 21 and a lower surface of the substrate S, thereby holding the substrate S under suction on the spin base 21. Together with the rotation of the spin base 21, the substrate S held under suction in this way rotates about the vertical axis AX. Hence, the occurrence of misalignment between a center SC of the substrate S and the center 21C of the spin base 21, namely, decentering of the substrate S reduces the quality of the bevel etching process

Accordingly, the centering mechanism 3 is provided in this embodiment. The centering mechanism 3 performs a centering operation while suction by the suction pump 24 is stopped (i.e. while the substrate S is horizontally movable on the upper surface 211 of the spin base 21). The above eccentricity is solved by this centering operation and the center SC of the substrate S is aligned with the center 21C of the spin base 21. Note that the detailed configuration and operation of the centering mechanism 3 are described later.

The processing liquid supply mechanism 4 is provided to perform the bevel etching process on the substrate S after implementation of the centering operation on the substrate S. The processing liquid supply mechanism 4 includes a processing liquid nozzle 41, a nozzle mover 42 that moves the processing liquid nozzle 41, and a processing liquid supplier 43 that supplies a processing liquid to the processing liquid nozzle 41. The nozzle mover 42 moves the processing liquid nozzle 41 between a retreat position to which the processing liquid nozzle 41 retreats laterally from a position above the substrate S as indicated by solid lines in FIG. 2 and a processing position above a peripheral edge part of the substrate S as indicated by dotted lines in FIG. 2.

The processing liquid nozzle 41 is connected to the processing liquid supplier 43. When a suitable processing liquid is supplied from the processing liquid supplier 43 to the processing liquid nozzle 41 located at the processing position, the processing liquid is ejected from the processing liquid nozzle 41 onto a peripheral edge part of the rotating substrate S. By doing so, the bevel etching process with the processing liquid is performed on the entire peripheral edge part of the substrate S.

Although not shown in FIG. 2, a splash guard is provided in such a manner as to surround the substrate holder 2 from the side. The splash guard collects droplets of a processing liquid blown off from the substrate S during implementation of the bevel etching process to effectively prevent the collected droplets from flying around the apparatus.

The configuration of the centering mechanism 3 will be described next by referring to FIGS. 2 to 5, 6A and 6B. The centering mechanism 3 has the function of determining the position of the substrate S by moving the substrate S horizontally on the upper surface 211 of the spin base 21 in such a manner as to align the center SC of the substrate S placed on the upper surface 211 of the spin base 21 with the center 21C of the spin base 21. As shown in FIG. 3, as viewed in the X direction, the centering mechanism 3 includes a contact member 31 arranged closer to an X2 direction (right-hand direction in FIG. 3) and a contact member 32 and a contact member 33 arranged closer to an X1 direction (left-hand direction in FIG. 3) with respect to the center 21C of the spin base 21. The centering mechanism 3 further includes a moving mechanism 34 for moving the contact members 31 to 33 in a horizontal direction.

The moving mechanism 34 includes a single mover 35 for moving the contact member 31, and a multi-mover 36 for moving the contact members 32 and 33 collectively. The single mover 35 is arranged closer to the X2 direction and the multi-mover 36 is arranged closer to the X1 direction with respect to the center 21C of the spin base 21.

The single mover 35 includes a fixed base 351, a rotary motor 352, a power transmitter 353, and a slider 354. The rotary motor 352 is mounted on the fixed base 351, and the power transmitter 353 and the slider 354 are stacked in this order over the fixed base 351. The rotary motor 352 is a driving source for moving the contact member 31 in the X direction. When the rotary motor 352 operates in response to a control command from the controller 9, a rotary shaft (not shown in the drawings) rotates. This rotary shaft extends from the top of the fixed base 351 to the power transmitter 353 and rotary driving force generated by the rotary motor 352 is transmitted to the power transmitter 353. Using a rack-and-pinion structure, for example, the power transmitter 353 converts rotary motion responsive to the rotary driving force to liner motion in the X direction, and transmits the linear motion to the slider 354. This makes the slider 354 move back and forth in the X direction by a distance responsive to the amount of the rotation. As a result, in response to the movement of the slider 354, the contact member 31 mounted on the top of the slider 354 is moved in the X direction.

The multi-mover 36 has a configuration basically the same as that of the single mover 35 except that a slider 364 has a partially different structure. Specifically, the multi-mover 36 applies rotary driving force generated by a rotary motor 362 mounted on a fixed base 361 to the slider 364 using a power transmitter 363, thereby moving the slider 364 in the X direction. The slider 364 has a top including two arms 364a and 364b extending in the X2 direction and separated from each other in a Y direction. The top of the slider 364 has a substantially C-shape in a plan view from vertically above. The contact members 32 and 33 are mounted on end portions closer to the X2 direction of the arms 364a and 364b respectively. Thus, when the rotary motor 362 operates in response to a control command from the controller 9, the slider 364 moves back and forth in the X direction by a distance responsive to the amount of the rotation of the rotary motor 362, like in the single mover 35. As a result, in response to the movement of the slider 364, the contact members 32 and 33 mounted on the slider 364 are moved in the X direction.

The contact members 31 to 33 have contact surfaces 311 to 331 capable of contacting the end face Se of the substrate S, respectively. With these contact surfaces 311 to 331 directed toward the end face Se of the substrate S, the contact members 31 to 33 are arranged so as to surround the substrate holder 2 in the XY plane (horizontal plane). The contact surfaces 311 to 331 have a planar shape, and their surface normals face the vertical axis AX. For example, as shown in section (a) of FIG. 4, on the contact surface 321, a linear region 322 that intersects a virtual horizontal plane including the substrate S placed on the upper surface of the substrate holder 2 functions as a “contactable region” of the present invention. Its length L is longer than the length Ln of the arc along which the circumference of the substrate S is cut off by the notch NT. Therefore, when the contact member 32 is moved toward the end face Se of the substrate S during centering, it contacts the end face Se of the substrate S at one or two points in the linear region 322. That is, as shown in FIG. 4, when the substrate S is placed on the upper surface of the spin base 21 with the notch NT facing the contact surface 321, the two contact points CP1 and CP2 on the linear region 322 contact on the end face Se of the substrate S. On the other hand, in other areas, one contact point on the linear region 322 contacts the end face Se of the substrate S. The same applies to the contact surfaces 311 and 331 as well. The reason why the contact members 31 to 33 are configured as described above will be described later in detail with reference to FIG. 4.

When the contact member 31 is moved in the X1 direction by the single mover 35, a contact surface 311 of the contact member 31 goes toward the center 21C of the spin base 21 to contact on the end face Se of the substrate S. As described above, in the present embodiment, a D1 direction in which the contact member 31 moves for abutting on the substrate S is the X1 direction, and this direction corresponds to a “first horizontal direction” of the present invention. After making the abutting contact, the contact member 31 moves further in the D1 direction, thereby moving the substrate S horizontally on the upper surface 211 of the spin base 21 in the X1 direction while pressing the substrate S in the X1 direction. In the present embodiment, to facilitate understanding of the substance of the invention, a virtual line VL extended in the X1 direction from the center 21C of the spin base 21 is additionally illustrated in FIGS. 3, 5, 6A and 6B. This line corresponds to a “virtual line” of the present invention. The configuration of the centering mechanism 3 will be described continuously using the virtual line VL in appropriate cases.

A configuration in which the contact members 32 and 33 are moved by the multi-mover 36 partially differs from that of the contact member 31. The reason for this is that the contact members 32 and 33 are arranged line-symmetrically to each other with respect to the virtual line VL in the horizontal plane and are moved in the X direction while being kept in this arrangement state. More specifically, as shown in a section (a) of FIG. 5, the contact member 32 is arranged at a position deviating from the virtual line VL by a predetermined distance W (shorter than a radius rs of the substrate S) to be closer to a Y2 direction. Meanwhile, the contact member 33 is arranged at a position deviating by the same distance W as the contact member 32 from the virtual line VL to be closer to the opposite side of the contact member 32 with respect to the virtual line VL, specifically, to be closer to a Y1 direction. Thus, when the contact members 32 and 33 are moved in the X2 direction by the multi-mover 36, a contact surface 321 of the contact member 32 contacts on the end face at a position closer to the Y2 direction than the virtual line VL. Furthermore, a contact surface 331 of the contact member 33 contacts on the end face at a position closer to the Y1 direction than the virtual line VL. As described above, in the present embodiment, a D2 direction in which the contact member 32 moves for abutting on the substrate S is the X2 direction, and this direction corresponds to a “second horizontal direction” of the present invention. A D3 direction in which the contact member 33 moves for abutting on the substrate S is also the X2 direction, and this direction corresponds to a “third horizontal direction” of the present invention. Thus, in order to move the contact surfaces 311, 321, and 331 while distances from the center 21C of the spin base 21 to the contact surfaces 311, 321, and 331 are kept equally, a movement amount per unit time is required to differ between the contact member 31 and the contact members 32, 33. This will be described in detail by referring to FIGS. 5 and 6A, and the centering operation using the above-described configuration of movement will also be described.

To place the substrate S on the upper surface 211 of the spin base 21, the contact surfaces 311, 321 and 331 are desirably positioned at reference positions at least in consideration of a maximum value of an outer diameter tolerance of the substrate S. For example, in the substrate S having a diameter of 300 mm, the outer diameter tolerance is 0.2 mm. Accordingly, the contact surfaces 311, 321 and 331 need to be separated from the center 21C of the spin base 21 by a distance of 150.1 mm or more. This distance is referred to as a “reference distance r0” in this embodiment and, as shown in field (a) of FIG. 5, a circle (one-dot chain line) having a radius centered on the center 21C of the spin base 21 and equal to the reference distance r0 is a reference circle.

Next, a case is studied where the contact surfaces 311, 321 and 331 are moved toward the substrate S after the contact members 31 to 33 are so positioned that the contact surfaces 311, 321 and 331 are located on the reference circle. In this case, the position of the contact member 31 for positioning the contact surface 311 on the reference circle corresponds to a “first reference position” of the invention, the position of the contact member 32 for positioning the contact surface 321 on the reference circle corresponds to a “second reference position” of the invention, and the position of the contact member 33 for positioning the contact surface 331 on the reference circle corresponds to a “third reference position” of the invention.

Out of these, the second and third reference positions are set to be line-symmetrical with each other with respect to a virtual line VL on a side (left side of FIG. 5(a)) opposite to the contact member 31 with respect to the center 21C of the spin base 21 in a horizontal plane as shown in FIG. 5(a). Moreover, the second and third reference positions are set at positions respectively inclined from the virtual line VL by a first angle θ1 and a second angle θ2 and separated from the center 21C of the spin base 21 by a reference distance r0. The first and second angles θ1, θ2 are set to be 40° or larger and 60° or smaller. The reason for that is described in detail later.

Here, a case is studied next, where the contact members 31 to 33 are located at the first reference position, the second reference position, and the third reference position respectively, the contact member 31 makes a tiny movement by a first movement amount Δd1 in the D1 direction (X1 direction) toward the substrate S. If each of the contact members 32 and 33 makes a tiny movement by the same distance in the D2 direction (X2 direction) in response to the movement of the contact member 31, the contact surfaces 311, 321, and 331 are separated by nonuniform distances from the center 21C of the spin base 21. Hence, repeating the tiny movements of the contact members 31 to 33 while keeping a uniform movement amount per unit time results in the failure to align the center SC of the substrate S with the center 21C of the spin base 21.

In contrast, as shown in field (b) of FIG. 5 and FIG. 6, the contact surfaces 311, 321 and 331 can be moved while keeping the distances from the center 21C of the spin base 21 to the respective contact surfaces 311, 321 and 331 equal by finely moving the contact member 32 in the D2 direction by a second movement amount Δd2 and finely moving the contact member 33 in the D3 direction by a third movement amount Δd3 to correspond to a fine movement of the contact member 31 in the D1 direction by a first movement amount Δd1.

FIG. 6A is a diagram schematically showing positional relationships between the contact member 32 and the center 21C of the spin base 21 before and after the fine movement. FIG. 6A shows a positional relationship between a circle centered on the center 21C of the spin base 21 and having a radius r1 and the contact member 32 and a positional relationship between a circle centered on the center 21C of the spin base 21 and having a radius r2 and the contact member 32. In FIG. 6A, the contact member 32 before the fine movement of the contact member 32 in the D2 direction by the second movement amount Δd2 is shown by a solid line and the contact member 32 after the fine movement is shown by a two-dot chain line. FIG. 6A shows a contact point 324 between the circle centered on the center 21C of the spin base 21 and having the radius r1 and the contact member 32 and a contact point 325 between the circle centered on the center 21C of the spin base 21 and having the radius r2 and the contact member 32.

As shown in FIG. 6, the contact points 324 and 325 are at different positions on the contact member 32. On the other hand, a straight line connecting the center 21C of the spin base 21 and the contact point 324 and a straight line connecting the center 21C of the spin base 21 and the contact point 325 overlap. Further, an angle between the straight line connecting the center 21C of the spin base 21 and the contact point 324 and a virtual line VL and an angle between the straight line connecting the center 21C of the spin base 21 and the contact point 325 and the virtual line VL are equal.

Thus, a fine moving distance Δd2 (corresponding to a “second movement amount” of the invention) of the contact member 32 and a fine moving distance Δd3 (corresponding to a “third movement amount” of the invention) of the contact member 33 can be set as follows:

$$Δ d 2 = Δ d 3 = ( r 1 - r 2 ) / cos θ = Δ d 1 / cos θ ,$$

$$r 1 = r 0 , and$$

$$r 2 = r 1 - Δ d 1 ,$$

where:
r1: distance from the center 21C to the contact surface 321 before the fine movement,
θ: angle between the straight lines connecting the center 21C of the spin base 21 and the contact points 324, 325 and the virtual line,
r2: distance from the center 21C to the contact surface 321 after the fine movement, and
W: separation distance of the contact member 32 from the virtual line VL.
   In this case, even after the fine movement, the distances from the center 21C of the spin base 21 to the contact surfaces 311, 321 and 331 are equal. By repeating such fine movements, the contact members 31 to 33 approach the substrate S while keeping the distances from the center 21C of the spin base 21 to the contact surfaces 311, 321 and 331 equal. Then, for example, if there is a deviation as shown in FIG. 5, the contact member 31 first contacts the substrate S and moves the substrate S in the D1 direction while the above fine movements are repeated (see field (c) of FIG. 5). Subsequent to that, the contact member 32 contacts the substrate S pushed by the contact member 31 and horizontally moves the substrate S. Then, if the distances from the center 21C of the spin base 21 to the contact surfaces 311, 321 and 331 become the radius of the substrate S as shown in field (d) of FIG. 5, the last contact member 33 also contacts the substrate S. In this way, the substrate S is sandwiched by the contact members 31 to 33 to stop a movement thereof, and the center SC of the substrate S is aligned with the center 21C of the spin base 21. In this way, the centering process of the substrate S can be performed.

In the present embodiment including the centering mechanism 3, the controller 9 controls each part of the substrate processing apparatus 10 to perform the centering operation described above and the subsequent bevel etching process. The controller 9 includes an arithmetic processor 91 composed of a computer with a central processing unit (CPU), a random access memory (RAM), etc., a storage 92 such as a hard disk drive, and a motor controller 93.

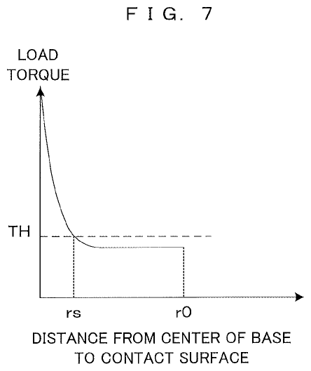

The arithmetic processor 91 reads a centering program and a bevel etching program as appropriate stored in advance in the storage 92, develops the program in the RAM (not shown in the drawings), and performs the centering operation and the bevel etching process shown in FIG. 5. In particular, in performing the centering operation, the arithmetic processor 91 calculates the first movement amount Δd1 to the third movement amount Δd3, and controls the rotary motors 352 and 362 of the moving mechanism 34 through the motor controller 93 on the basis of the calculated movement amounts Δd1 to Δd3. Furthermore, the arithmetic processor 91 calculates a load torque at the single mover 35 on the basis of a motor current value applied to the rotary motor 352 and calculates a load torque at the multi-mover 36 on the basis of a motor current value applied to the rotary motor 362. In response to change in a distance from the center 21C of the spin base 21 to each of the contact surfaces 311, 321, and 331 (a distance from the base center to the contact surface) occurring while the tiny movements are repeated, the load torque varies in a manner shown in FIG. 7, for example. As shown in FIG. 7, at a time when this distance conforms to the radius rs of the substrate S, specifically, when the substrate S is nipped with the contact members 31 to 33, the load torques increase steeply at the single mover 35 and the multi-mover 36 nearly simultaneously. At a time when the load torque exceeds a threshold, the arithmetic processor 91 determines that the centering operation is completed and stops the movements of the contact members 31 to 33. In the present embodiment, variation in the load torque at each of the motors 352 and 362 is monitored. Alternatively, only one of the motors may be monitored to determine timing of stopping movements of the contact members 31 to 33. Additionally, the load torque may certainly be calculated on the basis of an element other than the motor current value. These points also apply to a case where each of the contact members 31 to 33 is moved by a dedicated motor. Further, in the case of moving the contact members 31 to 33 by a single motor, calculation may be made based on a load torque and a motor current value of this motor.

As described above, in this embodiment, the contact members 31 to 33 are gradually brought closer to the substrate S while the distances of the contact surfaces 311, 321 and 331 from the center 21C of the spin base 21 are kept equal by repeating the minute movements of the contact members 31 to 33. Then, the center SC of the substrate S is aligned with the center 21C of the spin base 21 by sandwiching the substrate S by these three contact members 31 to 33. In this way, the centering operation is performed only by repeating the minute movements of the contact members 31 to 33, and the centering operation can be performed with excellent throughput (effect A).

Further, the completion of the centering operation is confirmed based on the load torque variation and the movements of the contact members 31 to 33 are immediately stopped. Thus, the centering operation can be finished at a proper timing without damaging the substrate S (effect B). This point applies also to embodiments to be described later.

Further, in this embodiment, each of the first and second angles θ1, θ2 is set in an acceptable range of 40° or larger and 60° or smaller. The reason for this is as follows.

To enhance the position accuracy of the substrate S in an advancing direction X of the substrate S and a horizontal direction Y orthogonal to the advancing direction X when the substrate S is minutely moved by the contact members 32 and 33, the substrate S is desirably easily movable on the spin base 21. As part of that, it is, for example, considered to reduce a friction force between the spin base 21 and the substrate S by interposing a nitrogen gas between the spin base 21 and the substrate S. Further, in this embodiment, polyether ether ketone (PEEK) is used as a constituent material of the spin base 21 to reduce the friction force. Besides these, the above first and second angles θ1, θ2 are present as elements directly related to the position accuracy of the substrate S. Accordingly, the inventors of this application conducted several experiments and found out that the first and second angles θ1, θ2 were preferably set in the acceptable range of 40° or larger and 60° or smaller to enhance the position accuracy of the substrate S. The acceptable range is described below with reference to FIGS. 6B, 8, 9A, 9B and 9C.

When the contact members 32, 33 are moved with a force F by the multi-mover 36, a pushing force of one contact member 32 to push the substrate S in the X2 direction is (F/2). The contact member 32 arranged and inclined by an angle θ with respect to the virtual line VL receives the above pushing force and gives the pushing force having an X-direction component Tx and a Y-direction component Ty to the substrate S. Out of these, the Y-direction component Ty of the pushing force is:

$$Ty = ( F / 2 ) * tan θ .$$

That is, as shown in FIG. 8(a), the Y-direction component Ty of the pushing force increases as the angle θ increases, overcomes the friction force between the spin base 21 and the substrate S and more easily moves the substrate S in the Y direction. Conversely, if the angle θ becomes smaller than 40°, it becomes difficult to move the substrate S in the Y direction as desired and, as shown in an experiment result to be described later, it is difficult to suppress the amount of eccentricity of the substrate S to a desired range, e.g. 10 μm (dashed-dotted line of FIG. 8(b)) or less even if the centering operation is performed. Therefore, the contact members 32, 33 are desirably arranged such that the first and second angles θ1, θ2 are respectively 40° or larger and an angle ∠ABC defined with a contact point between the substrate S and the contact member 32 set as A, the center 21C of the spin base 21 set as B and a contact point between the substrate S and the contact member 33 set as C is desirably set to 800 or larger.

On the other hand, increases of the first and second angles θ1, θ2 mean the setting of a longer separation distance W of the contact members 32, 33 from the virtual line VL as is clear from FIG. 5. This increase of the separation distance W leads to the enlargement of the multi-mover 36 and, consequently, causes the enlargement of the centering device. From the point of view of design, the angle θ is desirably suppressed to 60° or smaller and the angle ∠ABC is desirably set to 120° or smaller.

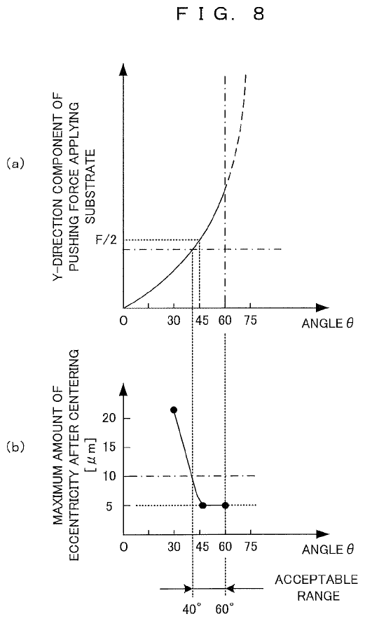

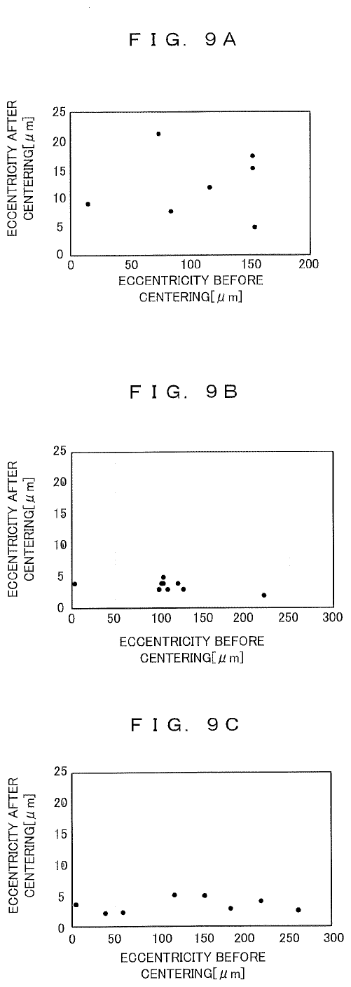

Accordingly, in the first embodiment, amounts of eccentricity before and after centering were actually measured while the angle ∠ABC was set to 60° (θ1=θ2=30°), 90° (θ1=θ2=45°) and 120° (θ1=θ2=60°). More specifically, the amounts of eccentricity were actually measured before and after centering every time the substrate S was placed on the spin base 21 and the centering operation was repeated. The amounts of eccentricity before and after centering for each centering operation are plotted in association with the angle ∠ABC of 60° in FIG. 9A, and it is understood that a maximum amount of eccentricity after centering is about 21 μm from FIG. 9A. FIGS. 9B and 9C are obtained for the angles ∠ABC of 90° and ∠ABC of 120° as in the case of the angle ∠ABC of 60°, and it is understood that the maximum amount of eccentricity after centering is about 5 μm from these figures. Further, the maximum amounts of eccentricity for the arrangement angle θ of the contact members 32, 33 are plotted in FIG. 8(b). As understood from FIG. 8(b), each of the first and second angles θ1, θ2 is preferably set to 40° or larger to suppress the amount of eccentricity to the desired range, e.g. 10 μm or less by the centering operation.

Based on such an analysis, the first and second angles θ1, θ2 are set in the acceptable range of 40° or larger and 60° or smaller in the first embodiment. Thus, the highly accurate centering operation can be performed with excellent throughput without causing the enlargement of the apparatus and the like (effect C).

Further, since the contact members 31 to 33 have linear regions 312, 322 and 332 formed to intersect the XY plane as shown in field (a) of FIG. 4, still other effects are obtained. As a technique for pushing and moving the end surface Se of the substrate S from a horizontal direction, contact members including tip parts finished into a semi-disk shape (see field (b) of FIG. 4) or tip parts finished into a sharp shape or contact members having a roller shape are generally used. Accordingly, the effects A, B and C described above are obtained by using contact members having these shapes.

However, for example, in the second embodiment shown in field (b) of FIG. 4, a tip part 393 of a contact member 39 has a semi-disk shape. In this contact member 39, a contact surface 391 facing the end face Se of the substrate S is finished into a convex shape toward the substrate S. Accordingly, on the contact surface 391, a curved region 392 intersecting a virtual horizontal plane including the substrate S placed on the upper surface of the substrate holder 2 has a curved shape having a center of curvature located on the side of the contact member 39. Thus, if the substrate S is placed on the upper surface of the spin base 21 with the notch NT facing the contact surface 391, a part of the tip part 393 is in contact with the substrate S at two contact points CP1, CP2 on the curved region 392 while entering the notch NT. As a result, at the time of centering, the contact surface 391 moves to a position P1 closer to the substrate S by the amount of eccentricity Lb than a position P0 where the contact surface 391 is positioned in contact with the end face Se of the substrate S. As a result, a pushing position of the contact member 39 deviates from a position for a precise centering process. For example, if the centering process was performed with the contact members 31 to 33 replaced by the contact members 39 in the centering mechanism 3 shown in FIG. 3, the following experimental result was obtained. Here, if the centering process was performed with the substrate (semiconductor wafer having a radius of 150 mm) placed on the spin base 21 rotated by a suitable rotation angle (e.g. 32°, 180° or 328°) about the vertical axis AX and the notch NT facing the contact surface 391, a deviation amount of the pushing position, i.e. the amount of eccentricity reached up to 240 μm.

In contrast, in the first embodiment, the contact surfaces 311 to 331 of the contact members 31 to 33 have a flat surface shape. Thus, as shown in field (a) of FIG. 4, a region (corresponding to an example of a “contactable region” of the invention) intersecting the virtual plane including the substrate S placed on the upper surface of the substrate holder 2 has a linear shape in each of the contact surfaces 311 to 331. Moreover, any of these linear regions 312, 322 and 332 is longer than an arc length Ln. Accordingly, if the substrate S is placed on the upper surface of the spin base 21 with the notch NT facing the contact surface 321 as shown in FIG. 4, two contact points CP1, CP2 on the linear region 322 are locked by shoulder parts of the notch NT, which can effectively prevent a part of the contact member 32 from entering the notch NT. Further, the contact surface 321 moves to a position P2 closer to the substrate S by an eccentric deviation amount La than a position P0 where the contact surface 321 is positioned in contact with the end face Se of the substrate S, but the amount of eccentricity La is drastically smaller than the amount of eccentricity Lb in the comparative example.

A combination of the centering mechanism 3 and the controller 9 corresponds to the first embodiment of the centering device according to the invention, but the configurations of the contact surfaces 311, 321 and 331 in the centering mechanism 3 are not limited to this. For example, the contact surfaces 311, 321 and 331 may be finished such that contactable regions intersecting the XY plane are curved as shown in FIG. 9 (third embodiment).

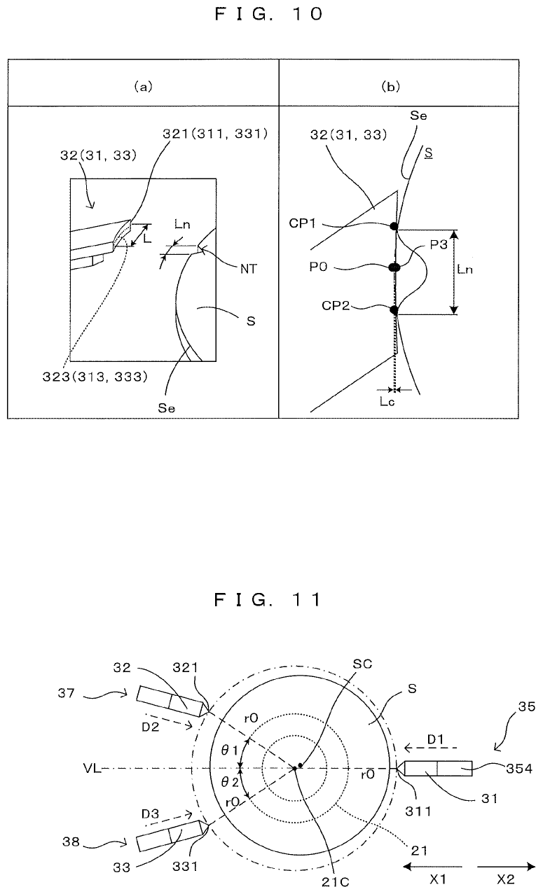

FIG. 10 is a diagram schematically showing the configuration of a contact member adopted in the third embodiment of the centering device according to the invention and a relationship with a notch of a substrate. This third embodiment largely differs from the first embodiment in that contact surfaces 311, 321 and 331 have a curved shape along an end face Se of a substrate S, and the other configuration is the same as in the first embodiment. Therefore, the following description is centered on points of difference and the same components are denoted by the same reference signs and are not described.

As shown in field (a) of FIG. 10, on a contact surface 321, a curved region 323 intersecting a virtual horizontal plane including the substrate S placed on the upper surface of a substrate holder 2 functions as a “contactable region” of the invention. That is, the contact surface 321 is finished such that a center of curvature of the curved region 323 is located on the side of the substrate S and a radius of curvature of the curved region 323 is larger than a radius of the substrate S. Accordingly, at the time of centering, the contact member 32 contacts the end face Se of the substrate S at one or two points in the curved region 323 if the contact member 32 is moved toward the end face Se of the substrate S. That is, as shown in FIG. 10, if the substrate S is placed on the upper surface of a spin base 21 with a notch NT facing the contact surface 321, two contact points P1, P2 on the curved region 323 are locked by shoulder parts of the notch NT, which can effectively prevent a part of the contact member 32 from entering the notch NT. Further, the contact surface 321 moves to a position P3 closer to the substrate S by an eccentric deviation amount Le than a position P0 where the contact surface 321 is positioned in contact with the end face Se of the substrate S, but the eccentric deviation amount Lc is smaller than the eccentric deviation amount La in the first embodiment. This point applies also to the contact surface 311 of the contact member 31 and the contact surface 331 of the contact member 33.

Here, if an eccentric deviation amount by the notch NT (angle of 1.119°) provided in the substrate S (semiconductor wafer having a radius of 150 mm) was obtained while the radius of curvature was changed in multiple stages, an experimental result shown in FIG. 10 was obtained. That is, the eccentric deviation amount L decreases as the radius of curvature approaches the radius of the substrate S. If the radius of curvature and the radius of substrate coincide, there is theoretically no influence of the notch NT. However, in consideration of tolerances of the substrate S, it is actually unusable to cause the radius of curvature to coincide with the radius of the substrate S. Therefore, in the third embodiment, the contact surfaces 311, 321 and 331 are finished such that radii of curvature of the curved regions 313, 323 and 333 are larger than the radius of the substrate S.

Note that the invention is not limited to the above embodiments and various changes other than the aforementioned ones can be made without departing from the gist of the invention. For example, in the above-described embodiments, nipping the substrate S with the contact members 31 to 33, namely, completion of the centering operation is detected on the basis of variation in a load torque. For example, the single mover 35 and the multi-mover 36 may be provided with a sensor such as a load sensor or strain gauge, a stress or strain may be detected by the sensors when the substrate S is sandwiched by the contact members 31 to 33 and detection signals may be output. In this case, the controller 9 confirms the sandwiching of the substrate S by the contact members 31 to 33 based on the detection signals from the sensors.

Further, although two contact members 32, 33 are respectively moved in the D2 direction (X2 direction) and the D3 direction (X2 direction) by the multi-mover 36 in the above embodiment, a single mover 37 for the contact member 32 and a single mover 38 for the contact member 33 configured similarly to the single mover 35 may be provided instead of the multi-mover 36 (fourth embodiment) as shown in FIG. 11.

Further, in the case of providing the single mover 37 for the contact member 32 and the single mover 38 for the contact member 33 in this way, there is no need to unify both the D2 direction and the D3 direction to the X2 direction. For example, as shown in FIG. 11, at least one of the D2 direction and the D3 direction may be changed from the X2 direction. Further, the values of the first and second angles θ1, θ2 are arbitrary as long as both a condition that the first angle θ1 is 40° or larger and 60° or smaller and a condition that the second angle θ2 is 40° or larger and 60° or smaller are satisfied as shown in FIG. 11.

In the above-described embodiments, the present invention is applied to the centering device provided to the substrate processing apparatus 10 that performs the bevel etching process. Meanwhile, the centering device according to the present invention is applicable to every type of centering device provided to a substrate processing techniques that performs a process while rotating a substrate of a circular plate shape and to and every type of centering method. Also, the centering device according to the present invention may be used alone.

Although the invention has been described with reference to specific embodiments, this description is not meant to be construed in a limiting sense. Various modifications of the disclosed embodiment, as well as other embodiments of the present invention, will become apparent to persons skilled in the art upon reference to the description of the invention. It is therefore contemplated that the appended claims will cover any such modifications or embodiments as fall within the true scope of the invention.

This invention can be applied to a centering technique for aligning a center of a disk-shaped substrate placed on the upper surface of a substrate support with a center of the substrate support and a substrate processing apparatus in general for processing a substrate utilizing the centering technique.

What is claimed is:

1. A centering device for positioning a substrate on a substrate support such that a center of the disk-shaped substrate placed in a horizontal posture on an upper surface of the substrate support is aligned with a center of the substrate support, the device comprising:
a first contact member movable in a horizontal plane in a first horizontal direction from a first reference position that is separated from the center of the substrate support by a reference distance longer than a radius of the substrate toward the center of the substrate support, the first horizontal direction being a direction toward the center of the substrate support;
a second contact member movable in the horizontal plane in a second horizontal direction from a second reference position that is inclined by a first angle with respect to a virtual line extending in the first horizontal direction from the center of the substrate support and separated from the center of the substrate support by the reference distance on a side opposite to the first contact member with respect to the center of the substrate support, the second horizontal direction being different from a direction toward the center of the substrate support and extending toward the substrate;
a third contact member movable in the horizontal plane in a third horizontal direction from a third reference position that is inclined by a second angle with respect to a virtual line and separated from the center of the substrate support by the reference distance on a side opposite to the first contact member with respect to the center of the substrate support and opposite to the second contact member with respect to the virtual line, the third horizontal direction being different from a direction toward the center of the substrate support and extending toward the substrate;
a moving mechanism configured to move the first contact member, the second contact member and the third contact member respectively in the first horizontal direction, the second horizontal direction and the third horizontal direction; and
a controller configured to perform an aligning the substrate with respect to the substrate support by controlling the moving mechanism, wherein
the first angle is in a range of 40° or larger and 60° or smaller,
the second angle is in a range of 40° or larger and 60° or smaller, and
the controller is configured to control the moving mechanism to repeat minute movements of moving the first contact member, the second contact member and the third contact member respectively by a first movement amount, a second movement amount and a third movement amount until contact of all of the first contact member, the second contact member and the third contact member with the substrate is completed so that distances of the first contact member, the second contact member and the third contact member from the center of the substrate support are kept equal.

2. The centering device according to claim 1, wherein:
the second horizontal direction and the third horizontal direction are directions parallel to the virtual line.

3. The centering device according to claim 2, wherein:
the third reference position is line-symmetrical with the second reference position with respect to the virtual line, and
the second movement amount and the third movement amount are equal.

4. A centering method for positioning a substrate on a substrate support such that a center of the disk-shaped substrate placed in a horizontal posture on an upper surface of the substrate support is aligned with a center of the substrate support, the method comprising:
placing the substrate on the upper surface of the substrate support with a first contact member located at a first reference position separated from the center of the substrate support by a reference distance longer than a radius of the substrate, a second contact member located at a second reference position inclined by a first angle with respect to a virtual line extending through the center of the substrate support from the first reference position and separated from the center of the substrate support by the reference distance on a side opposite to the first contact member with respect to the center of the substrate support and a third contact member located at a third reference position inclined by a second angle and separated from the center of the substrate support by the reference distance on a side opposite to the first contact member with respect to the center of the substrate support and opposite to the second contact member with respect to the virtual line;
repeating minute movements of moving the first contact member in a first horizontal direction from the first reference position toward the center of the substrate support by a first movement amount, moving the second contact member in a second horizontal direction different from a direction toward the center of the substrate support and extending toward the substrate from the second reference position by a second movement amount and moving the third contact member in a third horizontal direction different from a direction toward the center of the substrate support and extending toward the substrate from the third reference position by a third movement amount so that distances of the first contact member, the second contact member and the third contact member from the center of the substrate support are kept equal with the substrate placed horizontally movably on the upper surface of the substrate support; and
stopping the minute movements if sandwiching of the substrate by the first contact member, the second contact member and the third contact member is confirmed while the minute movements are repeated, wherein
the first angle is in a range of 40° or larger and 60° or smaller, and
the second angle is in a range of 40° or larger and 60° or smaller.

5. A substrate processing apparatus, comprising:
a substrate support having an upper surface and being configured to support a substrate in a horizontal posture;
the centering device according to claim 1;
a suction unit configured to suck and hold the substrate on the substrate support by exhausting air between the substrate positioned by the centering device and the substrate support;
a rotation driver configured to rotate the substrate support sucking and holding the substrate about a center of the substrate support; and
a processing liquid supply mechanism configured to supply a processing liquid to a peripheral edge part of the substrate rotated about the center of the substrate support integrally with the substrate support.
